(19) United States
(12) Patent Application Publication
(10) Pub. No.: US 2013/0263908 A1
(43) Pub. Date: Oct. 10, 2013

(54) Solar Cell Structure and Method for Manufacturing the Same

(71) Applicant: SUNOVEL SUZHOU TECHNOLOGIES LTD., Suzhou City (CN)

(72) Inventors: HUILONG ZHU, Poughkeepsie, NY (US); ZHIJIONG LUO, Poughkeepsie, NY (US); HAIZHOU YIN, Poughkeepsie, NY (US)

(73) Assignee: Sunovel Suzhou Technologies Ltd., Suzhou City (CN)

(21) Appl. No.: 13/858,396

(22) Filed: Apr. 8, 2013

(30) Foreign Application Priority Data
Apr. 6, 2012 (CN) 201210098644.X
Apr. 25, 2012 (CN) 201210124662.0

(51) Int. Cl. H01L 31/05

(52) U.S. Cl. CPC H01L 31/05
USPC 136/244; 438/66

(57) ABSTRACT

A solar cell structure is disclosed, which includes a solar cell array, including multiple solar cells arranged in parallel, wherein each solar cell includes a first semiconductor layer, a second semiconductor layer under the first semiconductor layer, top electrodes and bottom electrodes formed on surfaces of the first and second semiconductor layers, respectively; a top wire group on top of the solar cell array wherein each wire connects each of the multiple solar cells; a bottom wire group under the solar cell array wherein each wire connects each of the multiple solar cells and is placed away from the wires of the top wire group; and conductive adhesive on top of the top electrodes and on top of the bottom electrodes, being sandwiched between the top wire group and the solar cell array as well as between the bottom wire group and the solar cell array.

### FIELD OF THE INVENTION

The present invention relates to semiconductor manufacturing technology, particularly to solar cell manufacturing technology, and more particularly to a solar cell structure and a method for making the solar cell structure.

### BACKGROUND OF THE INVENTION

A conventional solar cell structure is typically an integral plate shape. Screen printing process is used to perform buses on conventional solar cells. During the screen printing process, the solar cell structure is first placed on a printing table, and then a precise screen fixed on a screen frame is placed above the solar cell. On the screen, there are to-be-printed patterns through which conductive paste can go through. Proper amount of conductive paste is put on the screen and daubed with a scraper so as fill in meshes of the screen uniformly. Some conductive paste is extruded and thus transferred onto the surface of the solar cell structure through the screen meshes with movement of the scraper. During this process, temperature, pressure, speed and other variables need to be controlled. In the above technology, because the solar cell structure is an integral structure, the conductive paste on one side of the solar cell structure cannot penetrate to the other side of the solar cell structure during the printing process.

However, with the innovation and development of solar cell technology, a new solar cell structure is provided. The new solar cell structure comprises separated solar cells connected by conductive wires. The area of such a solar cell structure h may be changed according to various application requirements. However, there is difficulty applying the above screen printing technology in such a solar cell structure because during the screen printing process the conductive paste on one side of the solar cells may go over to the other side of the solar cells and thus may result in cell shorting and degradation.

And thus, it is needed to provide a method for forming a wire bus of the solar battery, so as to avoid the above problems, make the solar battery be set easily according to practical requirements without influencing the performance of the solar battery, decrease manufacturing costs and make the solar battery be applied easily.

### SUMMARY OF THE INVENTION

The present invention provides a solar cell structure, which includes:

a solar cell array, including multiple solar cells arranged in parallel, wherein each solar cell includes a first semiconductor layer, a second semiconductor layer under the first semiconductor layer, top electrodes formed on the top surface of the first semiconductor layer and bottom electrodes formed on the surface of the second semiconductor layer;

a top wire group on the solar cell array wherein each wire of the top wire group connects each of the multiple solar cells;

a lower wire group under the solar cell array wherein each wire of the bottom wire group connects each of the multiple cells and is alternatively placed away from the wires of the top wire group; and

conductive adhesive being sandwiched between the top wire and the solar cell array and between the bottom wire group and the solar cell array and covering the top and bottom electrodes of each solar cell.

Optionally, there is an insulation layer covering the solar battery cell.

Optionally, the width of the solar cell is between 0.2 mm and 4 mm.

Optionally, the wires in the top and bottom wire groups have the same width.

Optionally, portions of the wires in the top and bottom wire groups which overlap the solar cells are wider than other portions of the wires in the top and bottom wire groups, and portions of the wires in the top and bottom wire groups which do not overlap the solar cells are thicker than other portions of the wires in the top and bottom wire groups.

Optionally, the conductive adhesive covers the entire internal surface of the wires.

Optionally, the conductive adhesive covers the internal surface of portions of the wires with which the electrodes are in contact.

Optionally, the electrodes have bonding pads for increasing contact interface with the wires.

The present invention also provides a method for making a solar cell structure, which includes:

a) providing a top wire group, wherein the internal surface of the top wire group is covered by conductive adhesive;

b) providing a solar cell array comprising multiple separated solar battery cells arranged in parallel, wherein each solar cell includes a first semiconductor layer, a second semiconductor layer under the first semiconductor layer, top electrodes formed on the top surface of the first semiconductor layer; and

c) placing the solar cell array on the top wire group so that the top wire group connect each of the multiple solar cells, wherein the surfaces of the wires covered by the conductive adhesive in the top wire group are in contact with the top electrodes of the solar cells;

d) forming bottom electrodes on the surface of the second semiconductor layer of each solar cell;

e) providing a bottom wire group, wherein the internal surface of the bottom wire group is covered by conductive adhesive; and

f) placing the solar cell array on the bottom wire group so that the bottom wire group connect each of the multiple solar cells, wherein the wires in the bottom wire group are alternatively placed away from the wires in the top wire group, and wherein the internal surfaces of the bottom wire group are in contact with the bottom electrodes of the solar cells.

Optionally, the step c) or the step f) further includes: drying the conductive adhesive.

Optionally, the covering the internal surface of the top wire group by conductive adhesive in the step a) and covering the internal surface of the bottom wire group by conductive adhesive in the step e) are implemented by a screen printing process.

Optionally, covering the internal surface of the top wire group by conductive adhesive in the step a) and/or covering the internal surface of the bottom wire group by conductive adhesive in the step e) include: patterning the conductive adhesive on the top wire group and/or the bottom wire group, so as to cover portions of the top wire group where the top electrodes are in contact by the conductive adhesive and/or cover portions of the bottom wire group where the bottom electrodes are in contact by the conductive adhesive.

Optionally, providing the top wire group in the step a) and/or providing the bottom wire group in the step e) include: making portions of the wires in the top and/or bottom wire groups which overlap the solar cells wider than other portions of the wires in the top and/or bottom wire groups, and making portions of the wires in the top and/or bottom wire groups which do not overlap the solar cells thicker than other portions of the wires in the top and/or bottom wire groups.

Optionally, the method further includes extruding the internal surfaces of the top and/or bottom wire groups by an extruder, so as to make the portions of the wires in the top and/or bottom wire groups which overlap the solar cells wider than other portions of the wires in the top and/or bottom wire groups, and make the portions of the wires in the top and/or bottom wire groups which do not overlap the solar cells thicker than other portions of the wires in the top and/or bottom wire groups.

Optionally, covering the internal surface of the top wire group by conductive adhesive in the step a) and covering the internal surface of the bottom wire group by conductive adhesive in the step e) include: selectively covering the top wire group by conductive adhesive and/or selectively covering the bottom wire group by conductive adhesive, such that the portions of the top wire group with which the top electrodes of the solar cells are in contact are covered by conductive adhesive and/or the portions of the bottom wire group with which the bottom electrodes of the solar cells are in contact covered by conductive adhesive.

Optionally, the step b) and the step d) further include: forming bonding pads for increasing contact interface with the wires on the top and/or bottom electrodes.

Optionally, the method further includes:

f) cutting the ends of the wires in the top wire group on one side of the solar cell array and cutting the ends of the wires in the bottom wire group on the other side of the solar cell array; and

g) forming output terminals of the solar cell structure.

Optionally, the step g) includes: bending the ends of the wires in the top wire group and bending the ends of the wires in the bottom wire group to form the output terminals of the solar cell structure.

Optionally, the step g) includes: forming a conductive connection between the ends of the wires in the top wire group and a conductive connection between the ends of the wires in the bottom wire group.

In the solar cell structure and the method for making the solar cell structure provided by the present invention, the solar cells in the solar cell array are separated from each other. Compared with the conventional integral solar cell structure, the solar cell structure provided by the present invention can avoid negative impact of the screen printing on the performance of the solar cells, and the area of the solar cell structure may be readily changed to meet applications needs. Moreover, the manufacturing costs of the solar cell structure are reduced, and the performance of the solar cell structure is improved.

### BRIEF DESCRIPTION OF THE DRAWINGS

The above and/or additional aspects and advantages of the present invention will become apparent and more readily appreciated from the following description of the exemplary embodiments, taken in conjunction with the accompanying drawings.

FIG. 1(a) is a top view of a wire in a top wire group according to a first embodiment of the present invention.

FIG. 1(b) is a cross-sectional view the A-A′ direction shown in FIG. 1(a).

FIG. 2(a) is a top view of a wire in the top wire group covered by conductive adhesive according to the first embodiment of the present invention.

FIG. 2(b) is a cross-sectional view along the A-A′ direction shown in FIG. 2(a).

FIG. 3(a) is a top view of a solar cell array according to the first embodiment of the present invention.

FIG. 3(b) is a cross-sectional view of the solar cell array along the A-A′ direction shown in FIG. 3(a).

FIG. 4(a) is a top view of the solar cell array placed on the top wire group according to the first embodiment of the present invention.

FIG. 4(b) is a cross-sectional view of the solar cell array along the A-A′ direction shown in FIG. 4(a).

FIG. 5(a) is a top view of the solar cell array shown in FIG. 4(a) on which bottom electrodes are set.

FIG. 5(b) is a cross-sectional view of the solar cell array along the A-A′ direction shown in FIG. 5(a).

FIG. 6(a) is a top view of a wire in a bottom wire group according to the first embodiment of the present invention.

FIG. 6(b) is a cross-sectional view along the B -B′ direction shown in FIG. 6(a).

FIG. 7(a) is a top view of a wire of the bottom wire group covered by conductive adhesive according to the first embodiment of the present invention.

FIG. 7(b) is a cross-sectional view along the B -B′ direction shown in FIG. 7(a).

FIG. 8(a) is a top view of the solar cell array placed on the bottom wire group according to the first embodiment of the present invention.

FIG. 8(b) is a cross-sectional view of the solar battery array along the A-A′ direction shown in FIG. 8(a).

FIG. 8(c) is a cross-sectional view of the solar battery array along the B-B′ direction shown in FIG. 8(a).

FIG. 9(a) is a top view of the solar cell array shown in FIG. 4(a) on which bottom electrodes with bonding panels are set.

FIG. 9(b) is a cross-sectional view of the solar cell array along the B-B′ direction shown in FIG. 9(a).

FIG. 10 is a top view of the solar cell array after the ends of wires in the top wire group on one side of the solar cell array are cut and the ends of wires in the bottom wire group on the other side of the solar cell array are cut.

FIG. 11 is a top view of the solar cell array after the ends of the wires in the top wire group are combined and bent and the ends of the wires in the bottom wire group are combined and bent.

FIG. 12 is a top view of the solar cell array in which conductive adhesive or electric welding are applied between the wires of the top wire group and/or between the wires of the bottom wire group.

FIG. 13(a) is a top view of a wire of the top wire group selectively covered by conductive adhesive according to a second embodiment of the present invention.

FIG. 13(b) is a cross-sectional view of a wire of the top wire group selectively covered with the conductive adhesive along the A-A′ direction shown in FIG. 13(a).

FIG. 14(a) is a top view of the solar cell array placed on the top wire group according to the second embodiment of the present invention.

FIG. 14(b) is a cross-sectional view of the solar cell array along the A-A′ direction shown in FIG. 14(a).

FIG. 15 is a top view of the solar cell array shown in FIG. 14(a) on which bottom electrodes are set.

FIG. 16(a) is a top view of a wire of the bottom wire group selectively covered by conductive adhesive according to the second embodiment of the present invention.

FIG. 16(b) is a cross-sectional view of a wire of the bottom wire group selectively covered by conductive adhesive along the B-B′ direction shown in FIG. 16(a).

FIG. 17(a) is a top view of the solar cell array placed on the bottom wire group according to the second embodiment of the present invention.

FIG. 17(b) is a cross-sectional view of the solar cell array along the A-A′ direction shown in FIG. 17(a).

FIG. 17(c) is a cross-sectional view of the solar cell array along the B-B′ direction shown in FIG. 17(a).

FIG. 18(a) is a top view of the solar cell array shown in FIG. 14(a) on which bottom electrodes with bonding pads are formed.

FIG. 18(b) is a cross-sectional view of the solar cell array along to B-B′ direction shown in FIG. 18(a) after the bottom electrodes are formed on the solar cell array.

FIG. 19 is a top view of a wire of the top wire group according to a third embodiment of the present invention.

FIG. 20(a) is a schematic diagram illustrating that a wire of the top wire group shown in FIG. 19 is extruded by an extruder.

FIG. 20(b) is a top view of a wire of the top wire group after the extrusion process shown in FIG. 19.

FIG. 20(c) is a cross-sectional view along the A-A′ direction shown in FIG. 20(b).

FIG. 21(a) is a top view of a wire of the top wire group selectively covered by conductive adhesive according to the third embodiment of the present invention.

FIG. 21(b) is a cross-sectional view along the A-A′ direction shown in FIG. 21(a).

FIG. 22(a) is a top view of the solar cell array that is placed on the top wire group and on which bottom electrodes are formed according to the third embodiment of the present invention.

FIG. 22(b) is a cross-sectional view the A-A′ direction shown in FIG. 22(a).

FIG. 23(a) is a top view of a wire of the bottom wire group selectively covered by conductive adhesive according to the third embodiment of the present invention.

FIG. 23(b) is a cross-sectional view along the B-B′ direction shown in FIG. 23(a).

FIG. 24(a) is a top view of the solar cell array placed on the bottom wire group according to the third embodiment of the present invention.

FIG. 24(b) is a cross-sectional view along the A-A′ direction shown in FIG. 24(a).

FIG. 24(c) is a cross-sectional view along the B-B′ direction shown in FIG. 24(a).

### DETAILED DESCRIPTION OF THE INVENTION

The embodiments of the present invention will be illustrated in details hereinafter. The examples of the embodiments are illustrated in the accompanying drawings, wherein like reference numerals indicate identical or functionally similar elements throughout. The embodiments illustrated with reference to the accompanying drawings are exemplary and only used to illustrate the present invention, but cannot be used to limit the present invention.

### First Embodiment

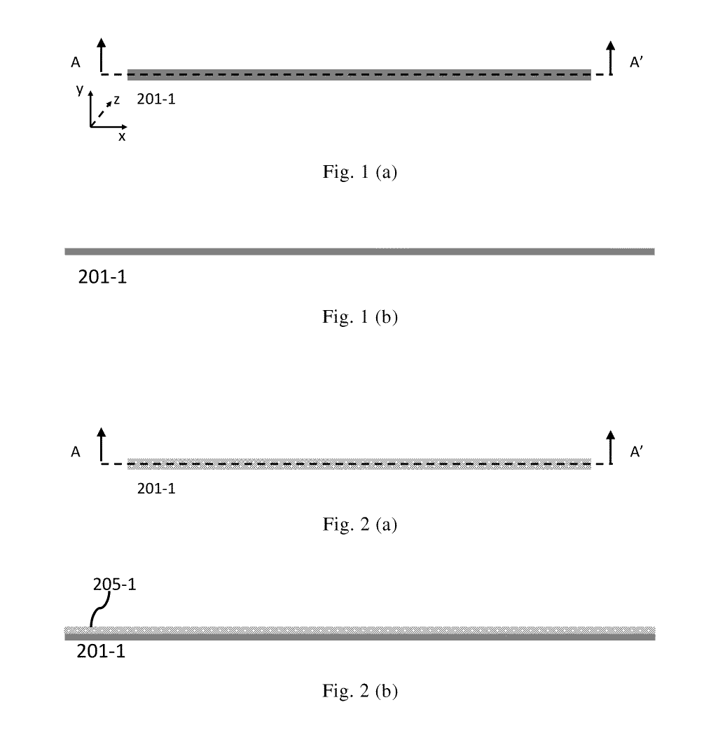

FIGS. 1-12 illustrate a process flow of making a solar cell structure according to the first embodiment of the present invention.

In step a),a top wire group is provided and the internal surface of the top wire group is covered by conductive adhesive (FIGS. 1(a) and 1(b)). FIG. 1(a) shows a top view of a wire 201-1 of the top wire group according to the embodiment of the present invention. FIG. 1(b) shows a cross-sectional view along the A-A′ direction shown in FIG. 1(a). Specifically, in this embodiment, the top wire group includes two wires 201-1 and 201-2, which are used to form a connection bus of solar cells. The wires may be copper wires, aluminum wires, silver wires, copper wires wrapped with TiN film or other conductive metal materials. In other embodiments, the top wire group may include one or more wires. The width of each wire is between 20 μm and 300 μm preferably, and the thickness of each wire is between 20 μm and 300 μm preferably. As shown in FIG. 1(a), the length of the wire refers to the dimension along x axis, the width of the wire refers to the dimension along y axis, and the thickness of the wire refers to the dimension along z axis. The cross section of the wire may be, but not limited to, a circle, an ellipse or a rectangle. As shown in FIGS. 2(a) and 2(b), only an internal surface of the top wire group is covered by conductive adhesive 205-1 through a screen printing method. The internal surface of the top wire group refers to the side which would be in contact with solar cells later in the process flow. FIG. 2(a) shows a top view of a wire of the top wire group covered with conductive adhesive according to the embodiment of the present invention, and FIG. 2(b) shows a cross-sectional view along the A-A′ direction as shown in FIG. 2(a). The conductive adhesive may be silver adhesive or other conductive adhesive. The thickness of the conductive adhesive may match the thickness of the top electrode which would be illustrated hereinafter, and is between 5 μm and 100 μm preferably.

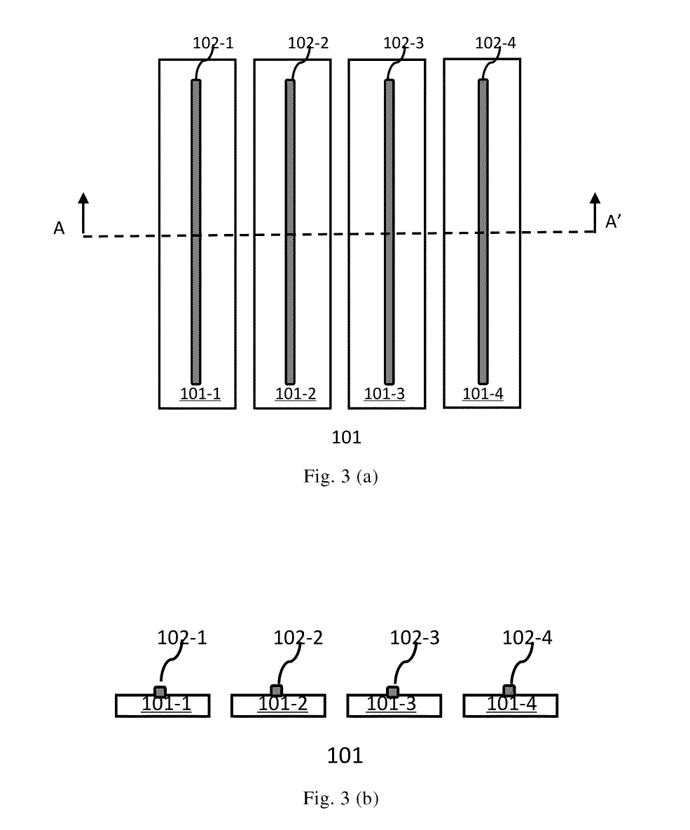

In step b), a solar cell array 101 is provided and includes multiple separated solar cells 101-1 . . . 101-4 arranged in parallel, wherein each solar cell includes a first semiconductor layer, a second semiconductor layer under the first semiconductor layer, and top electrodes 102-1 . . . 102-4 set on the top surface of the first semiconductor layer (FIGS. 3(a) and 3(b)). In other embodiments, each solar cell may further include an insulation layer (not shown in drawings) covering the sidewalls of the solar cell. Herein, the wording of “on” and “under” is only used to express a relative location relationship among components of the solar cell, but is not used to express the actual location of the components in final structure. Accordingly, when the solar cell is shifted, inverted or upended during a process of making the solar cell, the relative location relationship is maintained. Unlike the conventional integral solar cell structure, the solar cells 101-1 . . . 101-4 in the solar cell array 101 provided by the present invention are separated from each other, and the number of the solar cells and the area of each solar cell may be varied to meet different application requirements. For example, the area of each solar cell may be 10 cm×5 cm, and the width of each solar cell may be between 0.2 mm and 4 mm. The above-mentioned solar cell may different configurations. For example, the first semiconductor layer may be n-type and the second semiconductor layer may be p-type, or, the first semiconductor layer may be p-type and the second semiconductor layer may be n-type, or, a middle layer or other doped regions may be added. All these different configurations can be chosen based on application needs, but are not used to limit the present invention. The top electrode may be a metal finger. The materials of the top electrode include, but are not limited to, aluminum, silver, silver-lead alloy, nickel, copper and so on. The thickness of the top electrode is between 5 μm and 100 μm preferably.

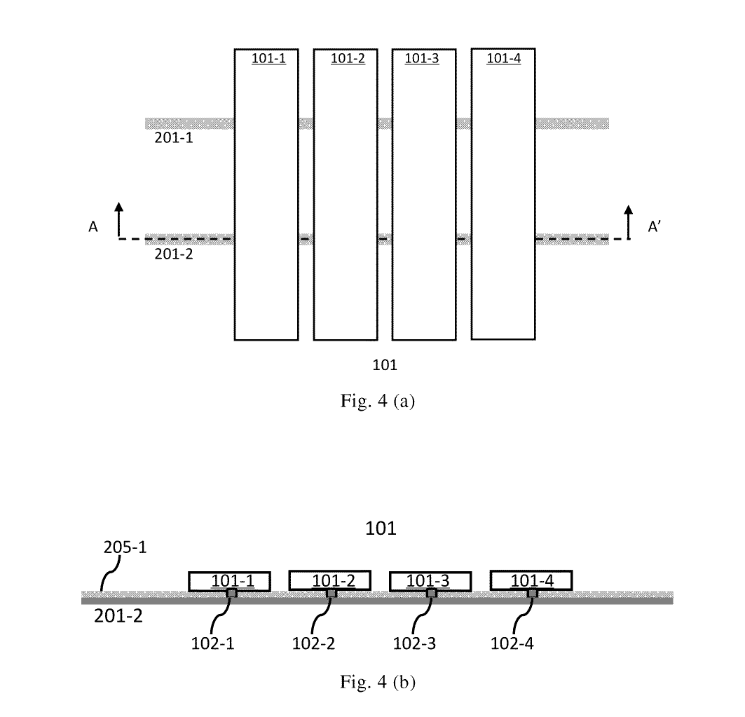

In step c), the solar cell array 101 is placed on the top wire group with wires 201-1 and 201-2 connecting each of the multiple solar cells 101-1 . . . 101-4, wherein the internal surfaces of the wires in the top wire group are covered by the conductive adhesive 205-1 and are in contact with the top electrodes 102-1 . . . 102-4 of the solar cells (FIGS. 4(a) and 4(b)). Especially, the solar cell array 101 may be flipped and placed on the top wire group with the wires 201-1 and 201-2 in this step.

Afterwards, the conductive adhesive 205-1 may be dried to avoid shift of the conductive adhesive which may degrade the performance of the solar cells. Optionally, this step may be omitted and the following step is performed directly.

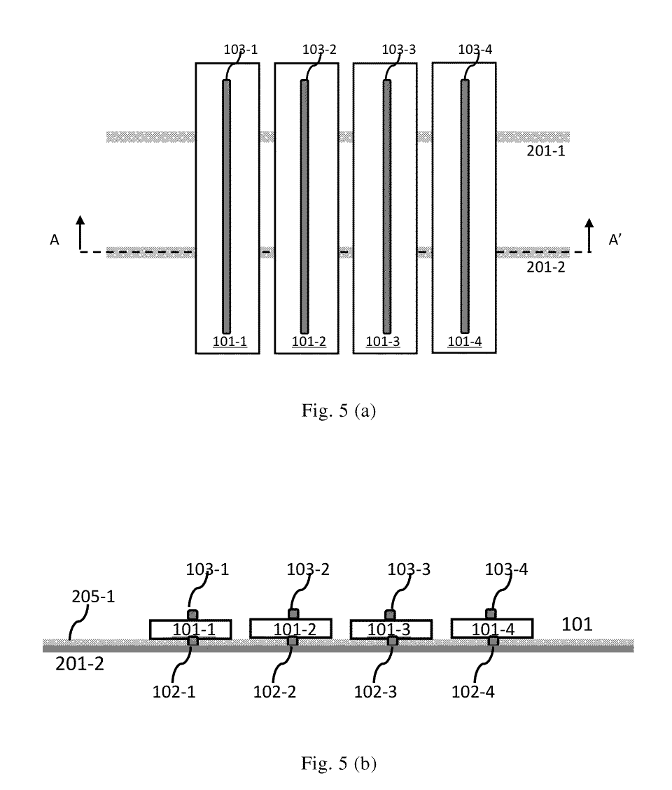

In step d), as shown in FIGS. 5(a) and 5(b), bottom electrodes 103-1 . . . 103-4 are formed on the surface of the second semiconductor layer of each of the solar cells 101-1 . . . 101-4. The bottom electrode may be a metal finger. The materials of the bottom electrodes include, but are not limited to aluminum, silver, silver-lead alloy, nickel, copper and so on. The thickness of the bottom electrodes is between 5 μm and 100 μm preferably.

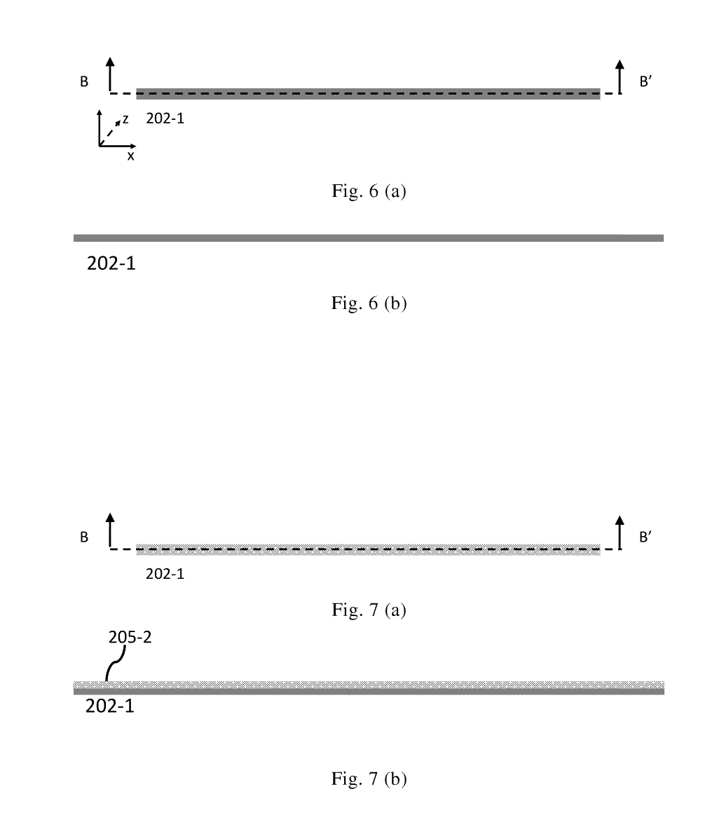

In step e), similar to the step a), a bottom wire group is provided and the internal surface of the bottom wire group is covered by conductive adhesive through a screen printing method (FIGS. 6(a) and 6(b)). The internal surface of the bottom wire group refers to the side which would be in contact with the solar cells later in the process flow. Specifically, in this embodiment, the bottom wire group includes two wires 202-1 and 202-2, which are used to form a bus connecting the solar cells. In other embodiments, the bottom wire group may include one or more wires. The wires may be copper wires, aluminum wires, silver wires, copper wires wrapped with TiN film or other conductive metal materials. The width of each wire is between 20 μm and 300 μm preferably, and the thickness of each wire is between 20 μm and 300 μm preferably. As shown in FIG. 6(a), the length refers to the dimension along x axis, the width of the wire refers to the dimension along y axis, and the thickness of the wire refers to the dimension along z axis. As shown in FIGS. 7(a) and 7(b), only the internal surface of the bottom wire group is covered by conductive adhesive 205-2. FIG. 7(a) shows a top view of a wire of the bottom wire group covered by the conductive adhesive according to the embodiment of the present invention, and FIG. 7(b) shows a cross-sectional view along the B-B′ direction as shown in FIG. 7(a). The conductive adhesive may be silver adhesive or other conductive adhesive. The thickness of the conductive adhesive may match the thickness of the bottom electrodes, and may be between 5 μm and 100 μm preferably.

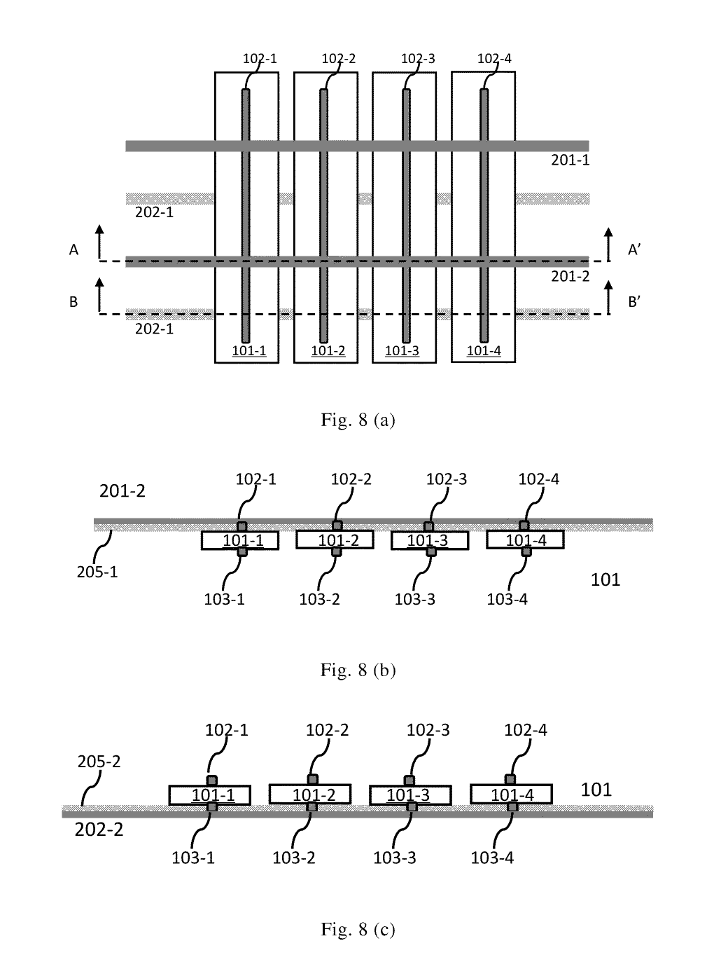

In step f), as shown in FIGS. 8(a) to 8(c), the solar cell array 101 is placed on the bottom wire group with wires 202-1 and 202-2, connecting each of the solar cells 101-1 . . . 101-4, wherein the wires 202-1 and 202-2 in the bottom wire group are alternatively placed away from the wires 201-1 and 201-2 in the top wire group and wherein the internal surfaces of the wires in the bottom wire group covered with the conductive adhesive 205-2 are in contact with the bottom electrodes 103-1 . . . 103-4 of the solar cells.

Afterwards, the conductive adhesive 205-2 may be dried to avoid the shift of the conductive adhesive which may degrade performance of the solar cells. Optionally, this step may be omitted.

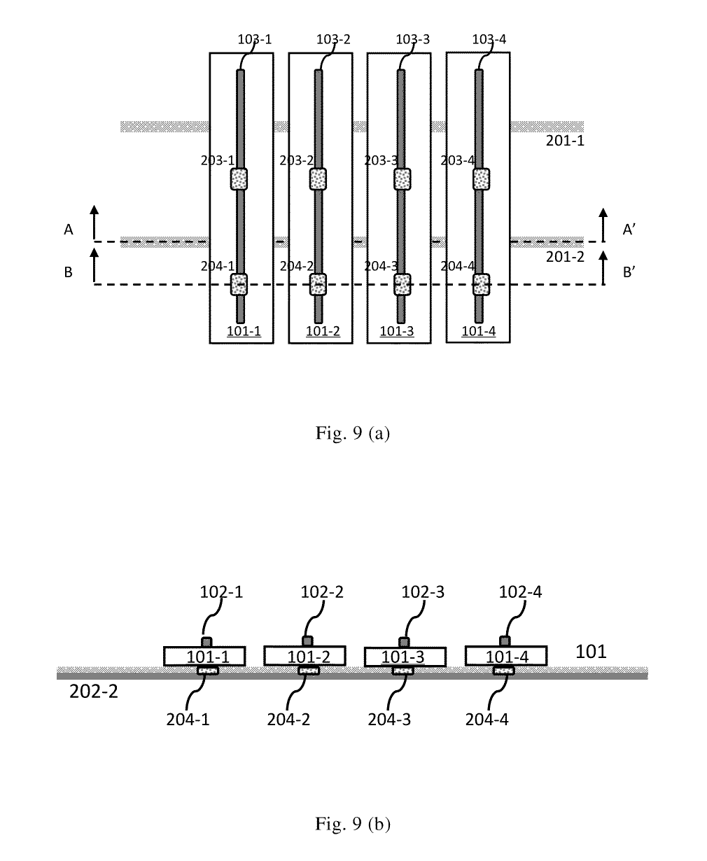

Optionally, as shown in FIGS. 9(a) and 9(b), the step d) may further include forming bonding pads 203-1 . . . 203-4 and 204-1 . . . 204-4 to increase the contact interface with the wires. Optionally, the step b) may also further include forming the bonding pads to increase the contact interface with the wires. The bonding pads may be silver bonding pads, aluminum bonding pads, etc.

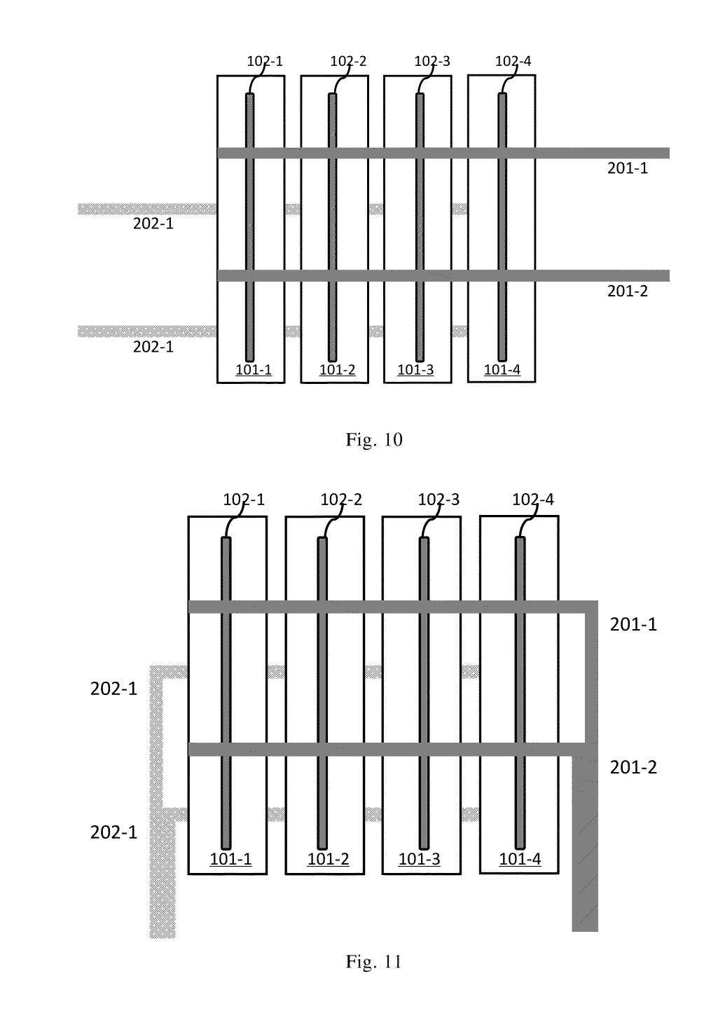

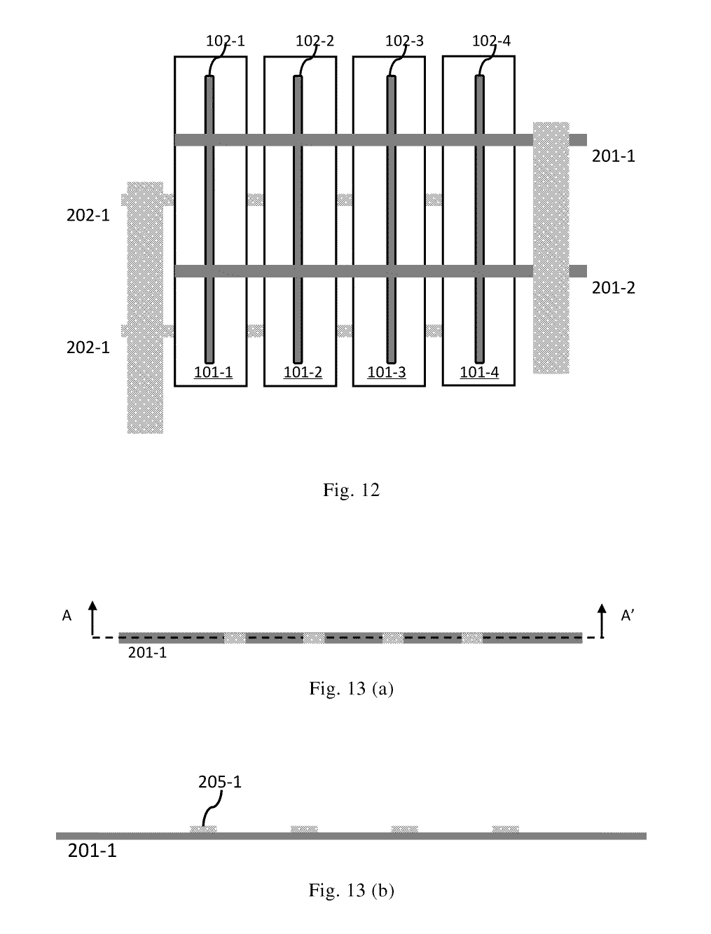

Afterwards, in step f), as shown in FIG. 10, the ends of the wires 201-1 and 201-2 in the top wire group are cut on one side of the solar cell array and the ends of the wires 202-1 and 202-2 in the lower wire group are cut on the other side of the solar cell array. In step g), as shown in FIGS. 11 and 12, output terminals of the solar cell structure are formed. That is to say, output terminals are formed between the ends of the wires 201-1 and 201-2 in the top wire group and between the ends of the wires 202-1 and 202-2 in the bottom wire group, respectively. For example, the ends of the wires in the top wire group may be combined and bent, and the ends of the wires in the bottom wire group may be combined and bent. Optionally, conductive adhesive or electric welding may be applied between the wires in the top wire group and/or between the wires in the bottom wire group.

The forgoing is a method for making the solar cell structure according to the first embodiment of the present invention. In the first embodiment, the wires in the top wire group and the bottom wire group, as provided in the step a) and the step e) respectively, have the same width. And in the step a) and the step e), the entire internal surfaces of the top wire group and bottom wire group are covered by conductive adhesive.

It should be noted that, in all embodiments and drawings of the present invention, the method is illustrated by taking as an example that the top wire group and the bottom wire group each include two wires, but the present invention is not limited to this case. The top wire group may include one wire or more than two wires. Similarly, the bottom wire group may also include one wire or more than two wires.

### Second Embodiment

The second embodiment will be illustrated hereinafter with reference to the accompanying drawings. The difference between the second embodiment and the first embodiment lies in that the step of covering the internal surfaces of the top wire group and bottom wire group by the conductive adhesive in the step a) and the step e) are replaced with a step of patterning the conductive adhesive on the top wire group and the bottom wire group, so as to cover portions of the top wire group where the top electrodes of the solar cells are in contact with the conductive adhesive and cover portions of the bottom wire group where the bottom electrodes of the solar cells are in contact with the conductive adhesive.

Specifically, in step a), as shown in FIGS. 13(a) and (b), a top wire group is provided and the conductive adhesive is patterned on the top wire group, so as to cover portions of the top wire group where the top electrodes of the solar cells are in contact with the conductive adhesive. The top wire group may be selectively covered by the conductive adhesive 205-1 using a screen printing method. In this embodiment, the top wire group includes two wires 201-1 and 201-2, which are used to form a bus of the solar cells. The wires may be copper wires, aluminum wires, silver wires, copper wires wrapped with TiN film or other conductive metal materials. The width of each wire is between 20 μm and 300 μm preferably, and the thickness of each wire is between 20 μm and 300 μm preferably. FIG. 13(a) shows a top view of a wire of the top wire group selectively covered by the conductive adhesive according to the embodiment of the present invention, and FIG. 13(b) shows a cross-sectional view along the A-A′ direction as shown in FIG. 13(a). The conductive adhesive may be silver adhesive or other conductive adhesive. The thickness of the conductive adhesive may match the thickness of top electrodes which would be illustrated hereinafter, and the thickness may be between 5 μm and 100 μm preferably.

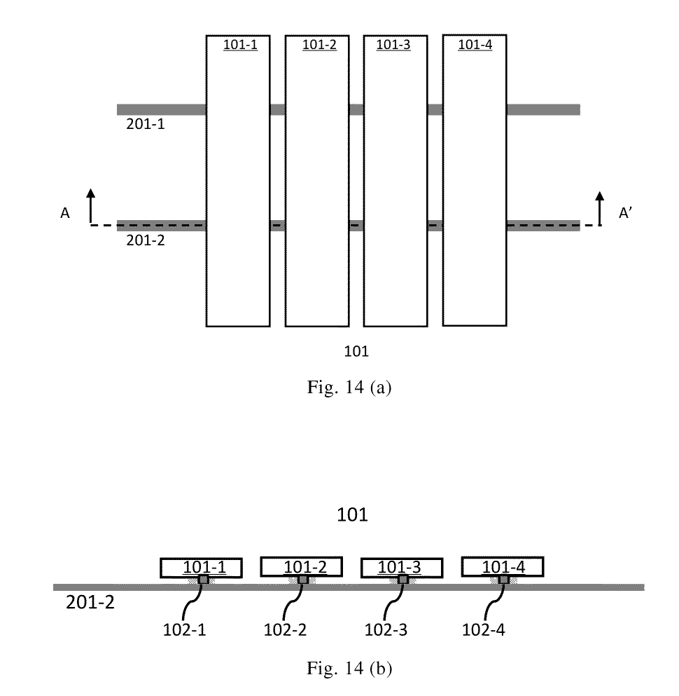

Afterwards, in step b), a solar cell array 101 is provided and includes multiple separated solar battery cells 101-1 . . . 101-4 arranged in parallel, wherein each solar cell includes a first semiconductor layer, a second semiconductor layer under the first semiconductor layer, and top electrodes 102-1 . . . 102-4 on the top surface of the first semiconductor layer. The step b) in the second embodiment is similar to the step b) in the first embodiment. In step c), as shown in FIGS. 14(a) and 14(b), the solar cell array 101 is placed on the top wire group with wires 201-1 and 201-2 connecting each of the multiple solar cells 101-1 . . . 101-4, wherein the portions of the top wire group covered by the conductive adhesive 205-1 are in contact with the top electrodes 102-1 . . . 102-4 of the solar cells. Especially, the solar cellarray 101 may be flipped and placed on the top wire group with the wires 201-1 and 201-2.

Afterwards, the conductive adhesive 205-1 may be dried to avoid shift of the conductive adhesive which may degrade the performance of the solar cells. Optionally, this step may be omitted, and the following step is performed directly.

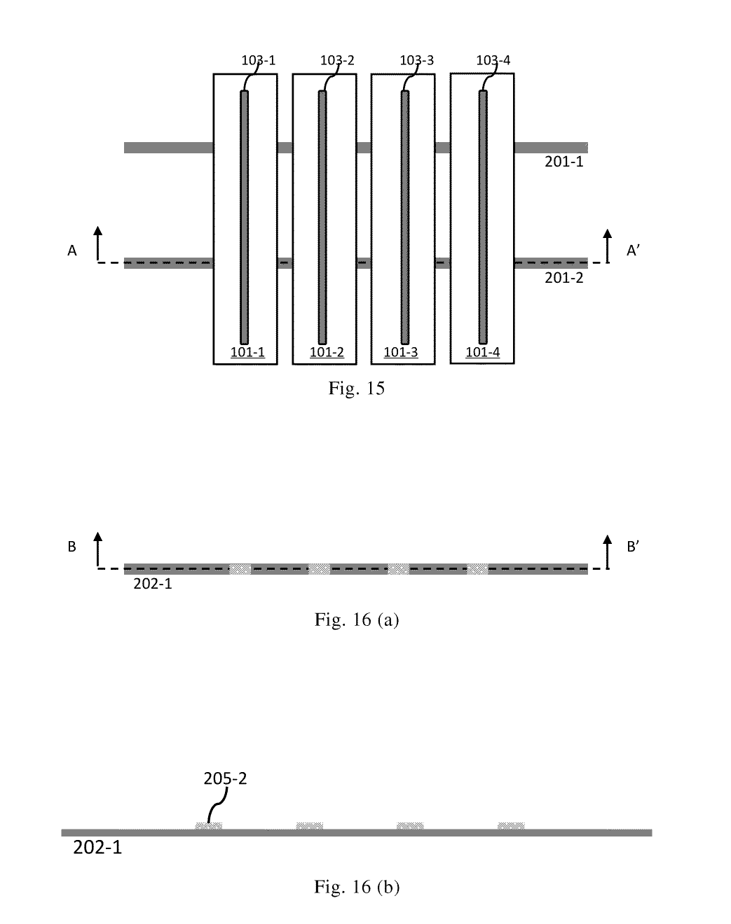

In step d), as shown in FIG. 15, bottom electrodes 103-1 . . . 103-4 are formed on the surface of the second semiconductor layer of each of the solar cells 101-1 . . . 101-4. The bottom electrode may be a metal finger. The materials of the bottom electrodes include, but are not limited to aluminum, silver, silver-lead alloy, nickel, copper and so on. The thickness of the bottom electrodes is between 5 μm and 100 μm preferably.

In step e), similar to the step a), a bottom wire group is provided and the conductive adhesive is patterned on the bottom wire group, so as to cover portions of the lower wire group where the bottom electrodes of the solar cells are in contact with the conductive adhesive 205-2 (FIGS. 16(a) and 16(b)). Specifically, the bottom wire group includes two wires 202-1 and 202-2, which are used to form a bus of the solar cells. The wires may be copper wires, aluminum wires, silver wires, copper wires wrapped with TiN film or other conductive metal materials. The width of each wire is between 20 μm and 300 μm preferably, and the thickness of each wire is between 20 μm and 300 μm preferably. FIG. 16(a) shows a top view of a wire of the bottom wire group covered with the conductive adhesive according to the embodiment of the present invention. FIG. 16(b) shows a cross-sectional view along the A-A′ direction as shown in FIG. 16(a). The conductive adhesive may be silver adhesive or other conductive adhesive. The thickness of the conductive adhesive may match the thickness of the bottom electrodes, and is between 5 μm and 100 μm preferably.

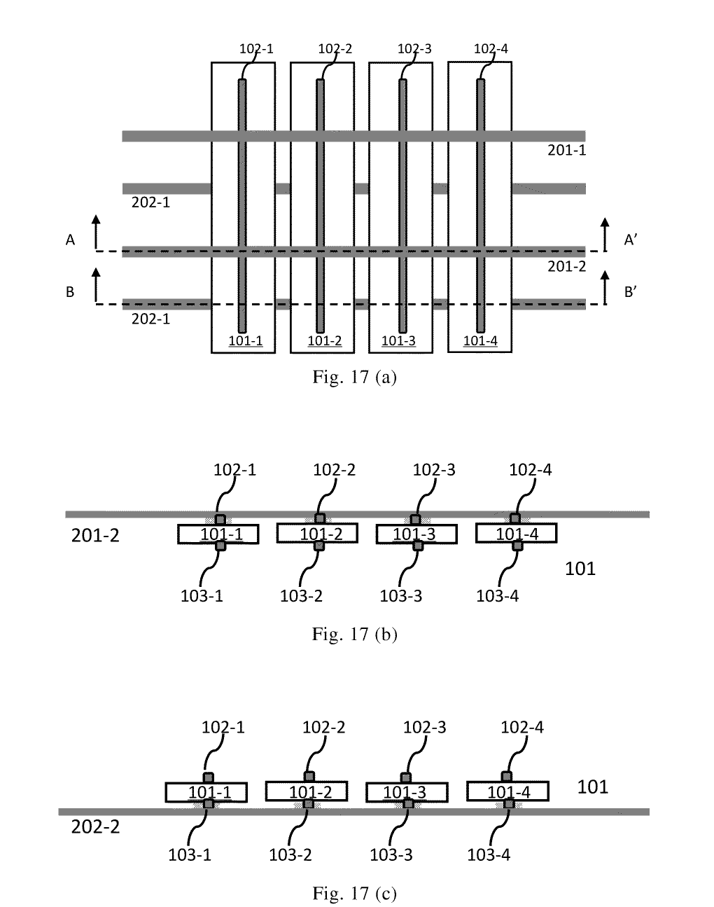

In step f), as shown in FIGS. 17(a) to 17(c), the solar cell array 101 is placed on the bottom wire group with wires 202-1 and 202-2 connecting each of the multiple solar ells 101-1 . . . 101-4, wherein the wires 202-1 and 202-2 in the bottom wire group are alternatively placed away from the wires 201-1 and 201-2 in the top wire group, and wherein the portions of the bottom wire group covered by the conductive adhesive 205-2 are in contact with the bottom electrodes 103-1 . . . 103-4 of the solar cells.

Afterwards, similar to the step c), optionally, the conductive adhesive 205-2 may be dried.

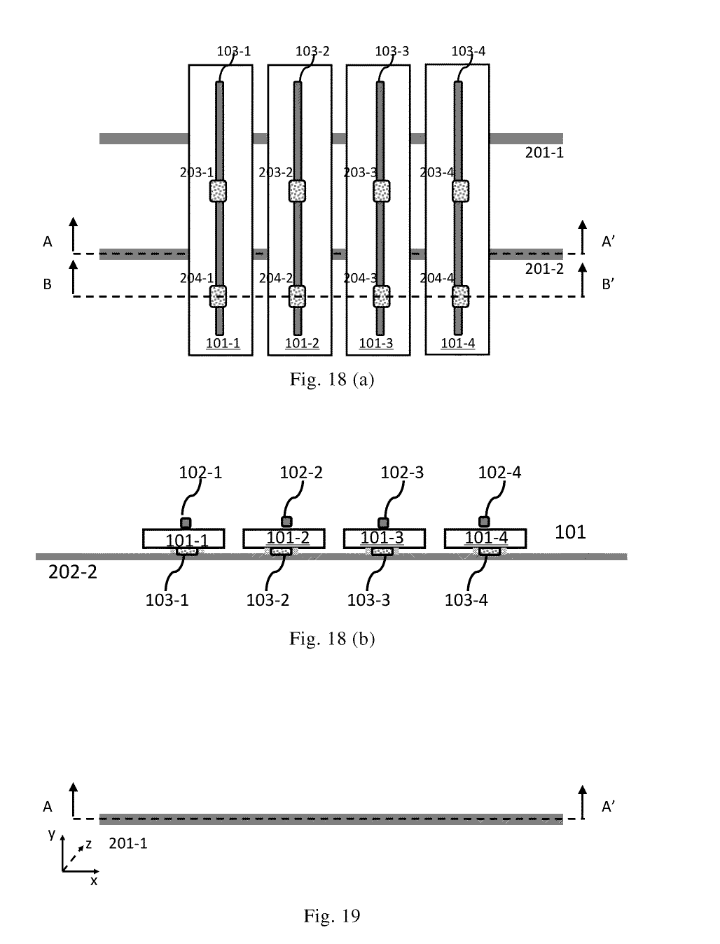

Optionally, as shown in FIGS. 18(a) and 18(b), the step d) may further include forming bonding pads 203-1 . . . 203-4 and 204-1 . . . 204-4 to increase the contact interface with the wires. Optionally, the step b) may also further include forming the similar bonding pads to increase the contact interface with the wires. The bonding pads may be silver bonding pads, aluminum bonding pads, etc.

Afterwards, in step f), similar to the first embodiment, the ends of the wires 201-1 and 201-2 in the top wire group are cut on one side of the solar cell array and the ends of the wires 202-1 and 202-2 in the bottom wire group are cut on the other side of the solar array. In step g), output terminals of the solar battery are formed. That is to say, output terminals are formed between the ends of the wires 201-1 and 201-2 in the top wire group and between the ends of the wires 202-1 and 202-2 in the bottom wire group, respectively. For example, the ends of the wires in the top wire group may be combined and bent and the ends of the wires in the bottom wire group may be combined and bent. Optionally, conductive adhesive or electric welding may be applied between the wires in the top wire group and/or between the wires in the bottom wire group.

The forgoing is a method for making the solar cell structure according to the second embodiment of the present invention. In the second embodiment, the internal surfaces of the top wire group and bottom wire group are selectively covered by conductive adhesive, so as to save costs without decreasing the performance of the solar cells.

### Third Embodiment

The third embodiment will be illustrated hereinafter with reference to the accompanying drawings. The difference between the third embodiment and the second embodiment lies in that the step a) further includes making portions of the wires in the top wire group which overlap the solar cells wider than other portions of the wires in the top wire group and making portions of the wires in the top wire group which do not overlap the solar cells thicker than other portions of the wires in the top wire group, and the step e) further includes making portions of the wires in the bottom wire group which overlap the solar cells wider than other portions of the wires in the bottom wire group and making portions of the wires in the bottom wire group which do not overlap the solar cells thicker than other portions of the wires in the bottom wire group. The step of covering the internal surfaces of the top wire group and the bottom wire group with the conductive adhesive is replaced with a step of patterning the conductive adhesive on the top wire group and the bottom wire group, such that the internal surfaces of the portions of the wires having the larger width are covered by the conductive adhesive. That is to say, the portions of the top wire group with which the top electrodes of the solar cells are in contact are covered by the conductive adhesive, and the portions of the bottom wire group with which the bottom electrodes of the solar cells are in contact are covered by the conductive adhesive.

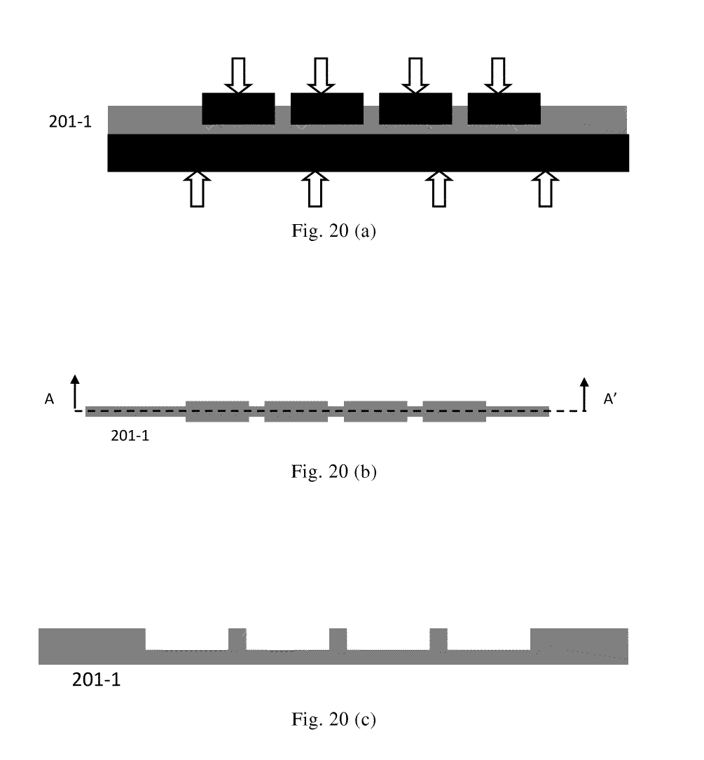

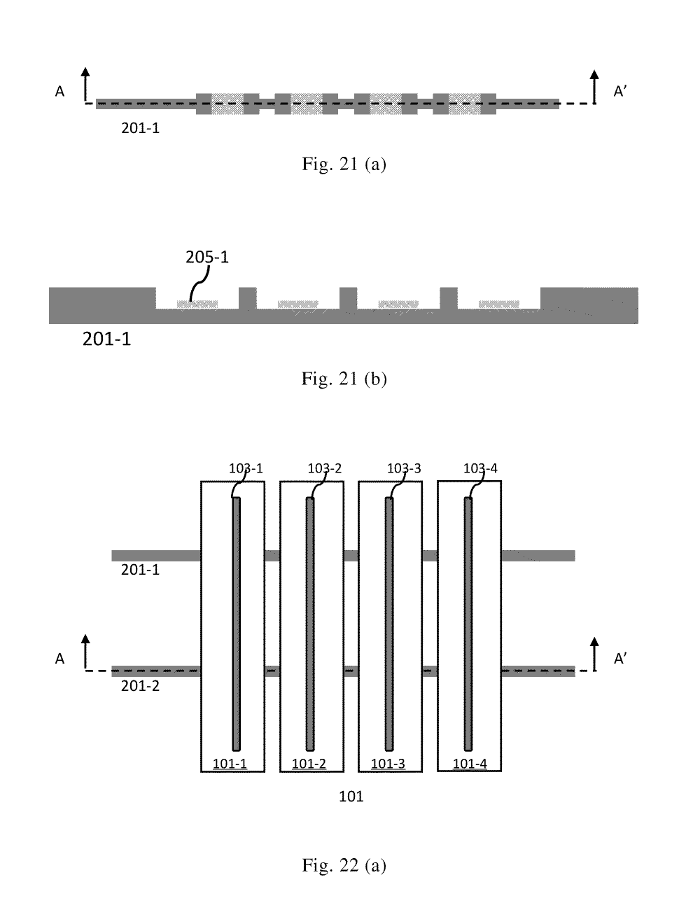

Specifically, in step a), a top wire group is provided (FIG. 19). In this embodiment, the top wire group includes two wires 201-1 and 201-2, which are used to form a bus of the solar cells. The wires may be copper wires, aluminum wires, silver wires, copper wires wrapped with TiN film or other conductive metal materials. The width of each wire is between 20 μm and 300 μm preferably, and the thickness of each wire is between 20 μm and 300 μm preferably. As shown in FIG. 20(a), the internal surface of the top wire group is extruded by an extruder, after which the portions of the wires in the top wire group that overlap the solar cells are wider than other portions of the wires in the top wire group, and the portions of the wires in the top wire group that do not overlap the solar cells are thicker than other portions of the wires in the top wire group. FIG. 20(b) shows a top view of a wire in the top wire group that is extruded. FIG. 20(c) is a cross-sectional view along the A-A′ direction as shown in FIG. 20(b). Afterwards, as shown in FIGS. 21(a) and 21(b), the top wire group is selectively covered by the conductive adhesive, such that the portions of the top wire group with which the top electrodes of the solar cells are in contact are covered by the conductive adhesive 205-1. The conductive adhesive may be silver adhesive or other conductive adhesive. The thickness of the conductive adhesive may match the thickness of the top electrodes which would be illustrated hereinafter, and is between 5 μm and 100 μm preferably.

Afterwards, in step b), a solar cell array 101 is provided and includes multiple separated solar cells 101-1 . . . 101-4 arranged in parallel, wherein each solar cell includes a first semiconductor layer, a second semiconductor layer under the first semiconductor layer, and top electrodes 102-1 . . . 102-4 on the top surface of the first semiconductor layer. The step b) in the third embodiment is similar to the step b) in the first embodiment.

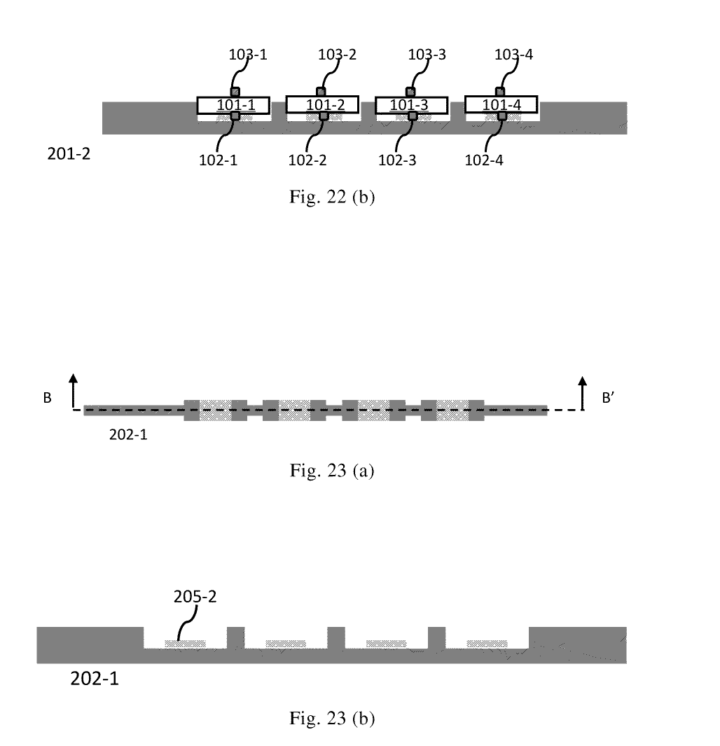

In step c), as shown in FIGS. 22(a) and 22(b), the solar array 101 is placed on the top wire group with wires 201-1 and 201-2 connecting each of the multiple solar cells 101-1 . . . 101-4, wherein the portions of the top wire group having the larger width are used to accommodate the solar cells, and wherein the portions of the top wire group covered with the conductive adhesive 205-1 are in contact with the top electrodes 102-1 . . . 102-4 of the solar cells. Optionally, the solar array 101 may be flipped and placed on the top wire group with the wires 201-1 and 201-2.

Afterwards, the conductive adhesive may be dried to avoid shift of the conductive adhesive which may degrade the performance of the solar celss. Optionally, this step may be omitted, and the following step is performed directly.

In step d), as shown in FIGS. 22(a) and 22(b), bottom electrodes 103-1 . . . 103-4 are formed on the surface of the second semiconductor layer of each of the solar cell 101-1 . . . 101-4. The bottom electrode may be a metal finger. The materials of the lower electrodes include, but are not limited to aluminum, silver, silver-lead alloy, nickel, copper and so on. The thickness of the bottom electrode is between 5 μm and 100 μm preferably.

In step e), similar to the step a), a bottom wire group is provided (FIGS. 23(a) and 23(b)). Specifically, the bottom wire group includes two wires 202-1 and 202-2, which are used to form a bus of the solar cells. The wires may be copper wires, aluminum wires, silver wires, copper wires wrapped with TiN film or other conductive metal materials. The width of each wire is between 20 μm and 300 μm preferably, and the thickness of each wire is between 20 μm and 300 μm preferably. The internal surface of the bottom wire group is extruded by an extruder, after which the portions of the wires in the bottom wire group which overlap the solar cells are wider than other portions of the wires in the bottom wire group, and the portions of the wires in the bottom wire group which do not overlap the solar battery cells are thicker than other portions of the wires in the bottom wire group. Afterwards, as shown in FIGS. 23(a) and 23(b), the bottom wire group is selectively covered by the conductive adhesive, such that the portion of the bottom wire group with which the bottom electrodes of the solar cells are in contact are covered by the conductive adhesive 205-2. The conductive adhesive may be silver adhesive or other conductive adhesive. The thickness of the conductive adhesive may match the thickness of the bottom electrodes, and is between 5 μm and 100 μm preferably.

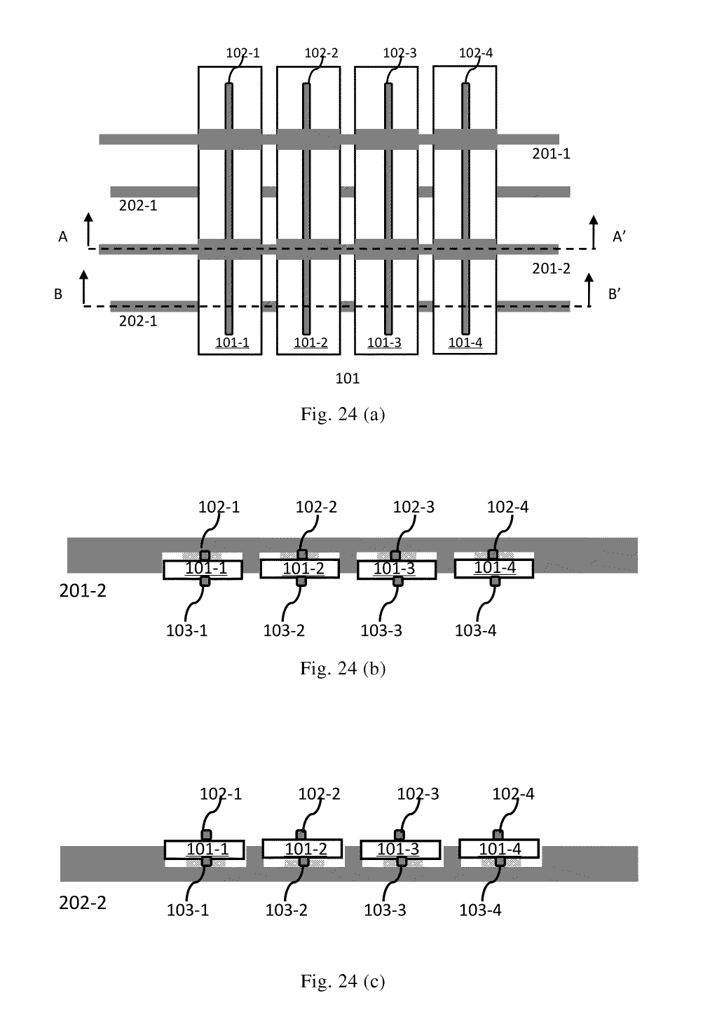

In step f), as shown in FIGS. 24(a) to 24(c), the solar cell array 101 is placed on the bottom wire group with the wires 202-1 and 202-2 connecting each of the multiple solar cells 101-1 . . . 101-4, wherein the wires 202-1 and 202-2 in the bottom wire group are alternatively placed away from the wires 201-1 and 201-2 in the top wire group, and wherein the portions of the bottom wire group having a larger width is used to accommodate the solar cells and the portions of the bottom wire group covered by the conductive adhesive are in contact with the bottom electrodes 103-1 . . . 103-4 of the solar cells.

Afterwards, similar to the step c), optionally, the conductive adhesive may be dried.

Optionally, the step d) may further comprise forming bonding pads 203-1 . . . 203-4 and 204-1 . . . 204-4 to increase the contact interface with the wires. Optionally, the step b) may also further comprise forming the bonding pads to increase the contact interface with the wires. The bonding pads may be silver bonding panels or aluminum bonding panels.

Afterwards, in step f), similar to the first embodiment, the ends of the wires 201-1 and 201-2 in the top wire group are cut on one side of the solar cell array and the ends of the wires 202-1 and 202-2 in the bottom wire group are cut on the other side of the solar cell array. In step g), output terminals of the solar cell structure are formed. That is to say, output terminals are formed between the ends of the wires 201-1 and 201-2 in the top wire group and between the ends of the wires 202-1 and 202-2 in the bottom wire group, respectively. For example, the ends of the wires in the top wire group may be combined and bent and the ends of the wires in the bottom wire group may be combined and bent. Optionally, conductive adhesive or electric welding may be applied between the wires in the top wire groups and/or between the wires in the bottom wire group.

All embodiments of the present invention have been illustrated with reference to the accompanying drawings.

The solar cell structure provided by the above embodiments includes a solar cell array 101, which includes multiple separated solar cells 101-1 . . . 101-4, wherein each solar cell includes a first semiconductor layer, a second semiconductor layer under the first semiconductor layer, top electrodes 102-1 . . . 102-4 on the top surface of the first semiconductor layer, and bottom electrodes 103-1 . . . 103-4 on the surface of the second semiconductor layer. The solar cell structure further includes an insulation layer covering the sidewalls of the solar cells, and an insulation layer covering the top and bottom surfaces of the solar cells. The solar cell structure further includes a top wire group with wires 201-1 and 201-2, which are set above the solar cell array 101 and connect each of the multiple solar cells, and a bottom wire group including wires 202-1 and 202-2, which are set under the solar cell array 101 and connect each of the multiple solar cells, wherein the wires in the bottom wire group are alternatively placed away from the wires in the top wire group. The solar cell structure further includes conductive adhesive, which is set between the top wire group and the solar cells and between the bottom wire groups and the solar cells, and is used to cover the top and bottom electrodes of each solar cell.

Optionally, the wires in the top wire group and bottom wire group have the same or different width. For example, the portions of the wires in the top wire group and the bottom wire group which overlap the solar battery cells are wider than other portions of the wires, and the portions of the wires in the top wire group and the bottom wire group which do not overlap the solar cells are thicker than other portions of the wires.

When the wires in the top wire group and the bottom wire group have the same width, the conductive adhesive may cover the whole internal surfaces of the wires or only cover portions of the internal surfaces of the wires with which the electrodes of solar cells are in contact.

Preferably, the top and bottom electrodes have bonding pads for increasing the contact interface with the wires.

Unline a conventional integral solar cell structure, the solar cell structure provided by the present invention includes solar cells separated from each other. Thus the area of the solar cell structure may be readily changed to meet specific application requirements. In conventional solar cell structures, bus formation is done by a screen printing process. Because the conventional solar cell structures are an integral unit, conductive paste cannot go from one side of the solar cell to the other side during a screen printing process. However, the screen printing process cannot be applied to the present invention to form buses. The solar cells in the present invention are separated from each other, and there is spacing between the solar cells. So when the screen printing process is applied to form buses across the solar cells on one side, the conductive paste can reach the other side of the solar cells, which may degrade the performance of the solar cells. The method of forming wire buses of the solar cell structure in the present invention solves the above problem. Moreover, the solar cells may be modified to meet specific application needs without degrading the performance of the solar cell structure, and manufacturing costs may be reduced.

The foregoing are only preferred embodiments of the present invention. It should be noted that those skilled in the art may make improvement and modification within the principle of the present invention, and the improvement and modification should be covered in the protection scope of the present invention.

1. A solar cell structure, comprising:
a solar cellarray, comprising multiple solar cells arranged in parallel, wherein each solar cell comprises a first semiconductor layer, a second semiconductor layer under the first semiconductor layer, top electrodes formed on the top surface of the first semiconductor layer and bottom electrodes formed on the surface of the second semiconductor layer;
a top wire group on the solar cell array wherein each wire of the top wire group connects each of the multiple solar cells;
a bottom wire group under the solar cell array wherein each wire of the bottom wire group connects each of the multiple solar cells and is alternatively placed away from the wires of the top wire group ; and
conductive adhesive being sandwiched between the top wire group and the solar cell array and between the bottom wire group and the solar cell array, and covering the top and bottom electrodes of each solar cell.

2. The solar cell structure of claim 1, wherein there is an insulation layer covering the solar cell.

3. The solar cell structure of claim 1, wherein the width of the solar cell is between 0.2 mm and 4 mm.

4. The solar cell structure of claim 1, wherein the wires in the top and bottom wire groups have the same width.

5. The solar cell structure of claim 1, wherein portions of the wires in the top and bottom wire groups which overlap the solar cells are wider than other portions of the wires in the top and bottom wire groups, and portions of the wires in the top and bottom wire groups which do not overlap the solar cells are thicker than other portions of the wires in the top and bottom wire groups.

6. The solar cell structure of claim 4, wherein the conductive adhesive covers the entire internal surface of the wires.

7. The solar cell structure of claim 4 or 5, wherein the conductive adhesive covers the internal surface of portions of the wires with which the electrodes are in contact.

8. The solar cell structure of claim 1, wherein the electrodes have bonding pads for increasing contact interface with the wires.

9. A method for making a solar cell structure, comprising:
a) providing a top wire group, wherein the internal surface of the top wire group is covered by conductive adhesive;
b) providing a solar cell array comprising multiple separated solar cells arranged in parallel, wherein each solar cell comprises a first semiconductor layer, a second semiconductor layer under the first semiconductor layer, top electrodes formed on the top surface of the first semiconductor layer; and
c) placing the solar cellarray on the top wire group so that the top wire group connect each of the multiple solar cells, wherein the surfaces of the wires covered by the conductive adhesive in the top wire group are in contact with the top electrodes of the solar cells;
d) forming bottom electrodes on the surface of the second semiconductor layer of each solar cell;
e) providing a bottom wire group, wherein the internal surface of the bottom wire group is covered by conductive adhesive; and
f) placing the solar cellarray on the bottom wire group so that the bottom wire group connect each of the multiple solar cells, wherein the wires in the bottom wire group are alternatively placed away from the wires in the top wire group, and wherein the internal surfaces of the bottom wire group are in contact with the bottom electrodes of the solar cells.

10. The method of claim 9, wherein the step c) or the step f) further comprises: drying the conductive adhesive.

11. The method of claim 9, wherein covering the internal surface of the top wire group by conductive adhesive in the step a) and/or covering the internal surface of the bottom wire group by conductive adhesive in the step e) are implemented by a screen printing process.

12. The method of claim 9, wherein covering the internal surface of the top wire group by conductive adhesive in the step a) and/or covering the internal surface of the bottom wire group by conductive adhesive in the step e) comprise: patterning the conductive adhesive on the top wire group and/or the bottom wire group, so as to cover portions of the top wire group where the top electrodes are in contact by the conductive adhesive and/or cover portions of the bottom wire group where the bottom electrodes are in contact with the conductive adhesive.

13. The method of claim 9, wherein providing the top wire group in the step a) and/or providing the bottom wire group in the step e) comprise: making portions of the wires in the top and/or bottom wire groups which overlap the solar cells wider than other portions of the wires in the top and/or bottom wire groups, and making portions of the wires in the top and/or bottom wire groups which do not overlap the solar cells thicker than other portions of the wires in the top and/or bottom wire groups.

14. The method of claim 13, further comprising extruding the internal surfaces of the top and/or bottom wire groups by an extruder, so as to make the portions of the wires in the top and/or bottom wire groups which overlap the solar cells wider than other portions of the wires in the top and/or bottom wire groups, and make the portions of the wires in the top and bottom wire groups which do not overlap the solar cells thicker than other portions of the wires in the top and/or bottom wire groups.

15. The method of claim 14, wherein covering the internal surface of the top wire group by conductive adhesive in the step a) and covering the internal surface of the bottom wire group by conductive adhesive in the step e) comprise: selectively covering the top wire group by conductive adhesive and/or selectively covering the lower wire group by conductive adhesive, such that the portions of the top wire group with which the top electrodes of the solar cells are in contact are covered by conductive adhesive and/or the portions of the lower wire group with which the bottom electrodes of the solar cells are in contact are covered by conductive adhesive.

16. The method of claim 9, wherein the step b) and/or the step d) further comprise: forming bonding pads for increasing contact interface with the wires on the top and/or bottom electrodes.

17. The method of claim 9, further comprising:
f) cutting the ends of the wires in the top wire group on one side of the solar cell array and cutting the ends of the wires in the bottom wire group on the other side of the solar cell array; and
g) forming output terminals of the solar cell structure.

18. The method of claim 17, wherein the step g) comprises: bending the ends of the wires in the top wire group and bending the ends of the wires in the bottom wire group to form the output terminals of the solar cell structure.

19. The method of claim 17, wherein the step g) comprises: forming a conductive connection between the ends of the wires in the top wire group and a conductive connection between the ends of the wires in the bottom wire group.
